(19) United States
(12) Patent Application Publication
(10) Pub. No.: US 2010/0019782 A1
(43) Pub. Date: Jan. 28, 2010

(54) CELLULAR POTENTIAL MEASUREMENT CONTAINER

(75) Inventors: Eiji Watanabe, Fukuoka (JP); Akira Higuchi, Fukuoka (JP); Masaya Nakatani, Hyogo (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Kadoma-shi, Osaka (JP)

(21) Appl. No.: 11/916,947

(22) PCT Filed: Jun. 28, 2006
(86) PCT No.: PCT/JP2006/313359

§ 371 Date: Dec. 7, 2007

(30) Foreign Application Priority Data
Jun. 29, 2005 (JP) 2005-190210
Jun. 29, 2005 (JP) 2005-190211
Jun. 29, 2005 (JP) 2005-190212
Jun. 29, 2005 (JP) 2005-190213

(51) Int. Cl. G01R 27/08

(52) U.S. Cl. 324/692

(57) ABSTRACT

The present invention provides a cellular potential measurement container that can measure a cellular potential with high accuracy while suppressing noise even when the number of the cells to be subjected to the measurement is increased. The cellular potential measurement container includes a first solution reservoir 14, a second solution reservoir 15, a partition substrate 18, a first electrode 27a, a second electrode 27b, a first measurement terminal 13a, and a second measurement terminal 13b. The first solution reservoir 14 and the second solution reservoir 15 are partitioned with the partition substrate 18, and the partition substrate 18 has a through hole 19. A first end of the through hole 19 is open toward the first solution reservoir 14 while a second end of the through hole 19 is open toward the second solution reservoir 15. The opening at the first end of the through hole 19 can hold a cell. The first electrode 27a is arranged so that a first solution can come into contact with the first electrode, and the second electrode 27b is arranged so that a second solution can come into contact with the second electrode. In the cellular potential measurement container with the above configuration, an electric signal amplifying device 16 further is provided, and the first measurement terminal 13a or the second measurement terminal 13b is connected to the first electrode 27a or the second electrode 27b via this electric signal amplifying device 16.

### TECHNICAL FIELD

The present invention relates to a cellular potential measurement container.

### BACKGROUND ART

In an early stage of electrophysiology, the membrane potential of a cell was measured by inserting a glass electrode into a cell, which led to the anticipation of the presence of ion channels in a cell membrane. With the development of a patch clamp method, significant progress was made in the measurement of a cell membrane potential. The patch clamp method was developed by Neher and Sakmann in 1976 (Neher E & Sakmann B (1976) Single channel currents recorded from membrane of denervated frog muscle fibers. Nature 260:799-802). This method made an astonishing achievement of actually demonstrating the presence of ion channels. In 1981, a whole-cell clamp method further was developed by Hamill et al. (Hamill O P, Marty A, Neher E, Sakmann B & Sigworth F J (1981) Improved patch-clamp techniques for high-resolution current recording from cells and cell-free membrane patches. Pflugers Arch 391: 85-100). By this method, it became possible to measure all the currents flowing through ion channels present all over the surface of a cell membrane. Because the whole-cell clamp method plays an important role in the development of pharmaceuticals, techniques for allowing this method to be performed rapidly have been developed. For example, a technique for performing a screening process rapidly has been proposed in which a plurality of through holes are provided on a flat panel device, a continuous cell layer is adhered to the flat panel device, and a potential-dependent ion channel activity is measured using an electrode (JP 2002-518678 A). However, because this technique requires that a plurality of cells are held on the substrate and the adjacent cells are bound firmly to each other, achieving an electrically sealed state is technically difficult. In order to solve this problem, a technique has been proposed in which electrophoresis utilizing a potential difference is used to perform the positioning of cells to be subjected to measurement as well as to achieve a tight electrical seal (Japanese Patent No. 3486171). Besides these techniques, an extracellular potential measurement device also has been proposed in which a plurality of wells are formed on a substrate, a recess for holding a cell is formed on the bottom of each well, and the recess is connected to suction means via a through hole (WO 02/055653 A1). With regard to this extracellular potential measurement device, a technique further has been proposed in which, in order to hold the cells still more reliably, a first opening, a second opening, and a hollow portion are formed on the bottom of the well. In this extracellular potential measurement device, the first opening holds a cell to be subjected to the measurement. The first opening and the second opening are connected to each other via the hollow portion, and the diameter of the first opening is smaller than that of the hollow portion, larger than that of the second opening, and smaller than that of the cell to be subjected to measurement (JP 2004-12215 A). Still further, a technique has been proposed in which an extracellular potential measurement device is configured so that, in order to attain a tight electrical seal of a cell, a diaphragm is provided on one surface of a substrate, a recess having at least one curved surface is provided on any of the surfaces of this diaphragm, a through hole is provided above the deepest portion of this recess, and a detecting electrode is provided in an opening of this through hole on the side opposite to the recess. With this configuration, the ion concentration of a culture solution in the through hole can be measured efficiently (JP 2004-271330 A). Similarly, a technique has been proposed in which an extracellular potential measurement device is configured so that, in order to attain a tight electrical seal of a cell, a diaphragm is provided on one surface of a substrate, a first recess is provided on any of the surfaces of this diaphragm, a through hole is provided in this first recess, a second recess is provided in an opening of this through hole on the side opposite to the first recess, and a detecting electrode is provided at a portion of this second recess. With this configuration, the ion concentration of a culture solution in the through hole can be measured efficiently (JP 2004-271331 A).

According to these techniques, it is possible to measure the extracellular potential of a plurality of cells and to attain tight electrical seal, thus allowing the measurement to be carried out with high accuracy. However, when the number of the cells to be subjected to the measurement is increased, there arises a problem in that electrical noise may be caused owing to a complicated electrical wiring or the like. None of the conventional techniques can solve the problem concerning the noise.

### DISCLOSURE OF INVENTION

With the foregoing in mind, it is an object of the present invention to provide a cellular potential measurement container that can measure a cellular potential with high accuracy while suppressing noise even when the number of the cells to be subjected to the measurement is increased.

In order to achieve the above object, the cellular potential measurement container according to the present invention includes: a measurement unit that includes a first solution reservoir, a second solution reservoir, a partition substrate, a first electrode, and a second electrode; a first measurement terminal; and a second measurement terminal. The measurement unit is configured so that the first solution reservoir and the second solution reservoir are partitioned with the partition substrate. The partition substrate has a through hole, and a first end of the through hole is open toward the first solution reservoir while a second end of the through hole is open toward the second solution reservoir. The opening at the first end of the through hole can hold a cell, the first electrode is arranged so that a first solution can come into contact with the first electrode, and the second electrode is arranged so that a second solution can come into contact with the second electrode. The cellular potential measurement container further includes an electric signal amplifying device and a power supply terminal. The power supply terminal is connected electrically to the electric signal amplifying device, and one of the first electrode and the second electrode is connected electrically to the first measurement terminal via the electric signal amplifying device while the other one of the first electrode and the second electrode is connected electrically to the second measurement terminal.

As described above, since the cellular potential measurement container of the present invention has the electric signal amplifying device, it is possible to suppress the noise. Therefore, even when the number of the cells to be subjected to the measurement is increased, for example, in order to perform high-speed screening and the wiring for transmitting an electric signal thus becomes long, it is possible to suppress the noise efficiently so that the cellular potential measurement can be carried out with higher accuracy than in the prior art. Also, when the number of the cells to be subjected to the measurement is small, the cellular potential measurement container according to the present invention still can suppress the noise more efficiently than the prior art.

### BRIEF DESCRIPTION OF DRAWINGS

FIG. 1 is a perspective view of a cellular potential measurement container according to one example of the present invention.

FIG. 2 is a plan view of the cellular potential measurement container according to the above example.

FIG. 3 is a sectional view of the cellular potential measurement container according to the above example, taken in the arrow direction of line A-A in FIG. 1.

FIG. 4 is an enlarged view showing a part of the sectional view of FIG. 3.

FIG. 5 is a perspective view of a substrate used in the cellular potential measurement container according to the above example.

FIGS. 6A, 6B, and 6C are sectional views showing a through hole of the substrate used in the cellular potential measurement container according to the above example.

FIG. 7 is a partially sectional perspective view showing a wiring structure of the cellular potential measurement container according to the above example.

FIG. 8 is a circuit diagram showing a wiring circuit of the cellular potential measurement container according to the above example.

FIG. 9 is a perspective view showing a part of the wiring structure according to the above example.

FIG. 10 is a partially sectional perspective view showing a wiring structure that is different from the wiring structure according to the above example.

FIG. 11 is a functional block diagram showing the configuration of an example of a cellular potential measurement device.

FIG. 12 is a perspective view showing an example of connection between the cellular potential measurement container according to the above example and the cellular potential measurement device.

FIG. 13 is a perspective view showing another example of connection between the cellular potential measurement container according to the above example and the cellular potential measurement device.

FIG. 14 is a plan view of a cellular potential measurement container according to another example of the present invention.

FIG. 15 is a circuit diagram showing a wiring circuit of the cellular potential measurement container according to the above example.

FIG. 16 is a plan view showing a cellular potential measurement container according to still another example of the present invention.

FIG. 17 is a circuit diagram showing a wiring circuit of the cellular potential measurement container according to the above example.

FIG. 18 is a circuit diagram showing another wiring circuit of the cellular potential measurement container according to the above example.

FIG. 19 is a sectional view of a cellular potential measurement container according to still another example of the present invention.

FIG. 20 is a circuit diagram showing another wiring circuit in Example 1.

### EXPLANATION OF REFERENCE NUMERALS

11 container main body plate

11a top plate

11b bottom plate

12 resin portion

13a first measurement terminal

13b second measurement terminal

14 first solution reservoir

15 second solution reservoir

16 electric signal amplifying device

17 switching device

18 partition substrate

19 through hole

20 second solution channel

21a second solution inlet

21b second solution outlet

22 protruding portion

23 resistor

24 encapsulation resin

25 power supply terminal

26 switching signal input terminal

27a first electrode

27b second electrode

28a first wiring pattern

28b second wiring pattern

29 conductive wire

30 measurement unit

31 cellular potential measurement device main body

32 electric signal measurement portion

33 power supply portion

34 switching signal output portion

35 record processing portion

36 storage portion

37 operation and input portion

38 display portion

39 cell

40 probe head main body

41 second probe holding portion

42 first probe holding portion

43, 44, 45, 46 probe

47 measurement stand

48, 49 connector terminal

121 resin portion

### DESCRIPTION OF THE INVENTION

The cellular potential measurement container according to the present invention is applicable to the measurement of an intracellular/extracellular potential across a cell membrane. The cellular potential is a signal whose value varies in accordance with, for example, the transfer of ions such as Na⁺, K⁺, Ca²⁺, and Cl⁻ across a cell membrane through ion channels present in the cell membrane, which is caused by, for example, activation of a receptor or the action of an intracellular signal transfer system. Furthermore, in the cellular potential measurement container according to the present invention, the cellular potential to be measured is at least one of a voltage and a current. That is, in the cellular potential measurement container according to the present invention, a voltage may be measured with a current being fixed, or a current may be measured with a voltage being fixed, for example. As described above, the change in cellular potential is caused by the change in transfer of ions. Hence, regardless of whether the measurement performed is the measurement of the change in current or the change in voltage, the fact remains that the change in transfer of ions is measured. Therefore, for example, in the cellular potential measurement container according to the present invention, when the change in voltage in a cell is to be measured, a voltage signal amplifying device may be used as the electric signal amplifying device and the change in voltage may be measured using the first measurement terminal and the second measurement terminal. On the other hand, when the change in current in a cell is to be measured, a current signal amplifying device may be used as the electric signal amplifying device and the change in current may be measured using the first measurement terminal and the second measurement terminal.

Preferably, the cellular potential measurement container according to the present invention includes a plurality of said measurement units. This is advantageous because the number of the cells that can be subjected to the measurement increases in accordance with the increase in the number of the measurement units. This allows the screening process to be performed still more rapidly, so that the screening of a pharmaceutical-candidate compound or the like can be performed still more rapidly, for example. Thus, the number of the cells that can be subjected to the measurement at a time can be, although not particularly limited, 1, 2, 3, 4, or more, preferably 16 to several hundreds, and more preferably, 16, 24, 96, 384, or the like, for example.

In the cellular potential measurement container according to the present invention, the electrical connection structure (wiring structure) in the case where a plurality of said measurement units are provided is not particularly limited.

For example, the cellular potential measurement container according to the present invention may include as many electric signal amplifying devices, first measurement terminals, and second measurement terminals as the measurement units, and the wiring structure may be such that the first electrodes are connected to the first measurement terminals via the electric signal amplifying devices on a one-to-one basis, and the second electrodes are connected to the second measurement terminals on a one-to-one basis.

Other than the above, in the cellular potential measurement container according to the present invention, a common wiring structure may be used. By using the common wiring structure, it is possible to simplify the wiring structure.

The cellular potential measurement container according to the present invention also may be configured so that, for example, it includes a plurality of said measurement units, a plurality of electric signal amplifying devices, a plurality of first measurement terminals, and a single second measurement terminal, wherein the first electrodes are connected to the first measurement terminals via the electric signal amplifying devices on a one-to-one basis, and the second electrodes are connected to the second measurement terminal through a common wiring structure.

Furthermore, the cellular potential measurement container according to the present invention also may be configured so that, for example, it includes a plurality of said measurement units, a plurality of electric signal amplifying devices, a plurality of first measurement terminals, and a single second measurement terminal, wherein the second electrodes are connected to the first measurement terminals via the electric signal amplifying devices on a one-to-one basis, and the first electrodes are connected to the second measurement terminal through a common wiring structure.

When the cellular potential measurement container according to the present invention includes a plurality of said measurement units, the switching of the measurement units may be performed by a switching device. In this case, the container may have the following two configurations, for example.

First, the first configuration is as follows. The cellular potential measurement container according to the present invention further includes a switching device and a switching signal input terminal. In this cellular potential measurement container, the switching device and the switching signal input terminal are connected electrically to each other, and one measurement group is constituted by the plurality of measurement units, the electric signal amplifying device, the first measurement terminal, the second measurement terminal, and the switching device. In the measurement group, the plurality of second electrodes are connected to the second measurement terminal through a common wiring structure, any one of the plurality of first electrodes is connected electrically to the first measurement terminal via the switching device and the electric signal amplifying device, and the first electrode to be connected electrically to the electric signal amplifying device and the first measurement terminal is selected from the plurality of first electrodes by the switching device.

Furthermore, the second configuration is as follows. The cellular potential measurement container according to the present invention further includes a switching device and a switching signal input terminal. In this cellular potential measurement container, the switching device and the switching signal input terminal are connected electrically to each other, and one measurement group is constituted by the plurality of measurement units, the electric signal amplifying device, the first measurement terminal, the second measurement terminal, and the switching device. In the measurement group, the plurality of first electrodes are connected to the second measurement terminal through a common wiring structure, any one of the plurality of second electrodes is connected electrically to the first measurement terminal via the switching device and the electric signal amplifying device, and the second electrode to be connected electrically to the electric signal amplifying device and the first measurement terminal is selected from the plurality of second electrodes by the switching device.

By using the switching device as described above, it is possible to reduce the number of the electric signal amplifying devices, for example. Thus, even when the number of the measurement units is increased, the configuration of the cellular potential measurement container according to the present invention can be simplified. Moreover, by using the switching device, it is possible to reduce the number of wirings, shorten the length of the wirings, and simplify the wiring structure. Therefore, by using the switching device, it becomes possible to suppress the noise further. When the cellular potential measurement container includes the switching device, one or a plurality of said measurement groups may be provided. When the plurality of said measurement groups are provided, the screening process can be performed still more rapidly.

The cellular potential measurement container according to the present invention may be configured so that it further includes a second solution channel, wherein one or a plurality of said measurement units are arranged above the second solution channel, the second solution reservoir communicates with the second solution channel, and an opening at one end of the second solution channel serves as an inlet for the second solution while an opening at the other end of the second solution channel serves as an outlet for the second solution. In this case, for example, one such second solution channel may be formed with respect to each of the measurement groups. Since a plurality of said measurement units can be arranged above this second solution channel, the configuration of the container does not become complicated even when the number of the cells to be subjected to the measurement is increased. Furthermore, by using the second solution channel, the second solution can be supplied to the plurality of said measurement units at once, instead of supplying the second solution to each of the measurement units. This allows the screening to be performed still more rapidly.

When the cellular potential measurement container according to the present invention includes the second solution channel, it is preferable that flow direction control means or a flow direction controller for causing the second solution to flow toward the second solution reservoir is arranged at a position corresponding to the second solution reservoir in the second solution channel. Although there is no particular limitation on the flow direction control means, it is preferable that the flow direction control means is a protruding portion formed inside the second solution channel, for example.

When the cellular potential measurement container according to the present invention includes the second solution channel, it is preferable that the cellular potential measurement container includes a plurality of said second solution channels, and one or a plurality of said measurement units are formed above each of the second solution channels.

The cellular potential measurement container according to the present invention may be configured so that, for example, the second solution reservoir is arranged below the first solution reservoir.

The cellular potential measurement container according to the present invention may be configured so that, for example, the first electrode is arranged on a surface of the partition substrate on the first solution reservoir side, and the second electrode is arranged on a surface of the partition substrate on the second solution reservoir side.

The cellular potential measurement container according to the present invention may be configured so that, for example, the partition substrate has a plurality of said through holes.

There is no particular limitation on the form of the cellular potential measurement container according to the present invention. For example, the cellular potential measurement container according to the present invention may be in the following form. That is, the cellular potential measurement container includes: a container main body plate; a resin portion; a partition substrate; a first electrode; a second electrode; a first wiring; a second wiring; a first measurement terminal; and a second measurement terminal and is configured so that a hole is formed on a surface of the container main body plate. The partition substrate is arranged on the surface of the container main body plate so as to cover the hole, the partition substrate has a through hole, the resin portion is provided on the surface of the container main body plate so as to surround the through hole, and a space surrounded by the resin portion serves as a first solution reservoir for storing a first solution. An interior of the hole serves as a second solution reservoir for storing a second solution, a first end of the through hole is open toward the first solution reservoir while a second end of the through hole is open toward the second solution reservoir, the opening at the first end of the through hole can hold a cell, the first electrode is arranged on a surface of the partition substrate so that the first solution can come into contact with the first electrode, and the second electrode is arranged on a rear surface of the partition substrate so that the second solution can come into contact with the second electrode. In this cellular potential measurement container, the first solution reservoir, the second solution reservoir, the partition substrate, the first electrode, and the second electrode constitute a measurement unit, and the first wiring, the second wiring, the first measurement terminal, and the second measurement terminal are arranged on the surface of the container main body plate. The cellular potential measurement container further includes an electric signal amplifying device and a power supply terminal. The power supply terminal is connected electrically to the electric signal amplifying device, and one of the first electrode and the second electrode is connected electrically to the first measurement terminal via the electric signal amplifying device while the other one of the first electrode and the second electrode is connected electrically to the second measurement terminal. In the cellular potential measurement container in the above-described form, the electric signal amplifying device and the power supply terminal may be arranged on the surface of the container main body plate. Moreover, when the cellular potential measurement container further includes the switching device and the switching signal input terminal as described above, they also are arranged on the surface of the container main body plate and can be connected electrically in the manner described above. When the cellular potential measurement container according to the present invention is in the above-described form, the configuration thereof does not become complicated even when the number of the cells to be subjected to the measurement is increased. Therefore, the cellular potential measurement container can be made denser to cope with an increase in the number of the cells to be subjected to the measurement, thus allowing the screening of a pharmaceutical-candidate compound or the like still more rapidly, for example.

The cellular potential measurement container according to the present invention in the above-described form may be configured so that it includes a plurality of said measurement units, and the resin portion is provided for each of the measurement units. Alternatively, the cellular potential measurement container according to the present invention in the above-described form may be configured so that it includes a plurality of said measurement units, the resin portion is a resin plate having a plurality of holes, and the resin plate is arranged on the surface of the container main body plate in such a manner that the plurality of holes form the first solution reservoirs of the plurality of the measurement unit.

The cellular potential measurement container according to the present invention in the above-described form may be configured so that the first measurement terminal and the second measurement terminal are arranged at end portions on the surface of the container main body plate.

When the cellular potential measurement container according to the present invention in the above-described form includes the second solution channel, the cellular potential measurement container may be configured so that the second solution channel is formed inside the container main body plate, and the hole forming the second solution reservoir communicates with the second solution channel. A first end of the second solution channel is open at the surface of the container main body plate so as to serve as an inlet for the second solution while a second end of the second solution channel is open at the surface of the container main body plate so as to serve as an outlet for the second solution. In this case, the cellular potential measurement container also may be configured so that one end of the second solution channel is open at the surface of the container main body plate so that this opening communicates with a through hole of the resin portion and an opening of this through hole serves as the inlet for the second solution, while the other end of the second solution channel is open at the surface of the container main body plate so that this opening communicates with another through hole of the resin portion and an opening of this through hole serves as the outlet for the second solution. Preferably, flow direction control means for causing the second solution to flow toward the second solution reservoir is arranged at a position corresponding to the second solution reservoir in the second solution channel. Although there is no particular limitation on the flow direction control means, it is preferable that the flow direction control means is a protruding portion formed inside the second solution channel. Preferably, the cellular potential measurement container includes a plurality of said second solution channels, and one or a plurality of said measurement units are formed above each of the second solution channels.

In the cellular potential measurement container according to the present invention in the above-described form, it is preferable that the first wiring includes a wiring pattern formed on the surface of the container main body plate and a conductive wire, and the wiring pattern and the first electrode connected electrically to each other through the conductive wire. Furthermore, in the cellular potential measurement container according to the present invention in the above-described form, it is preferable that the second wiring is a wiring pattern formed on the surface of the container main body plate, and the second electrode on the rear surface of the partition substrate is arranged on an end portion of the wiring pattern.

In the cellular potential measurement container according to the present invention in the above-described form, it is preferable that the first wiring and the second wiring are encapsulated with the resin portion either partially or entirely. When the cellular potential measurement container includes the conductive wire, it is preferable that at least the conductive wire is encapsulated with the resin portion. Furthermore, in the cellular potential measurement container according to the present invention in the above-described form, it is preferable that an edge portion of the partition substrate is covered with the resin portion.

In the following, the present invention will be described by way of examples. It is to be noted, however, the present invention is by no means limited to the following examples.

### EXAMPLE 1

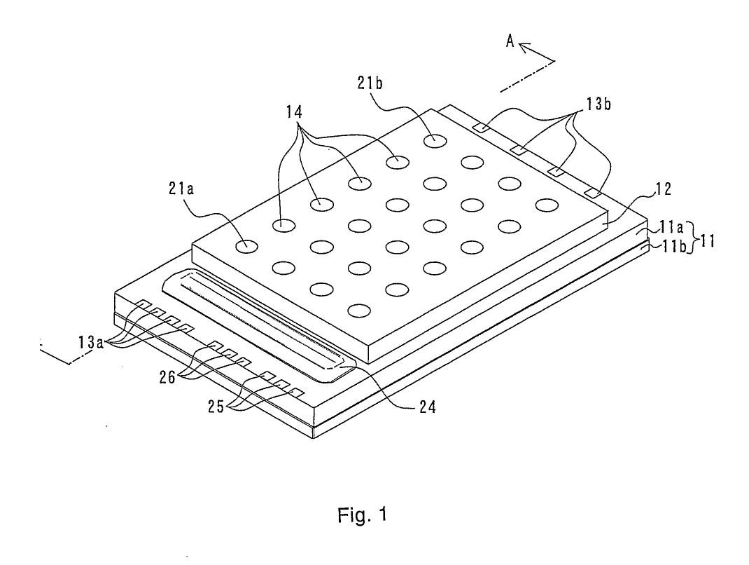

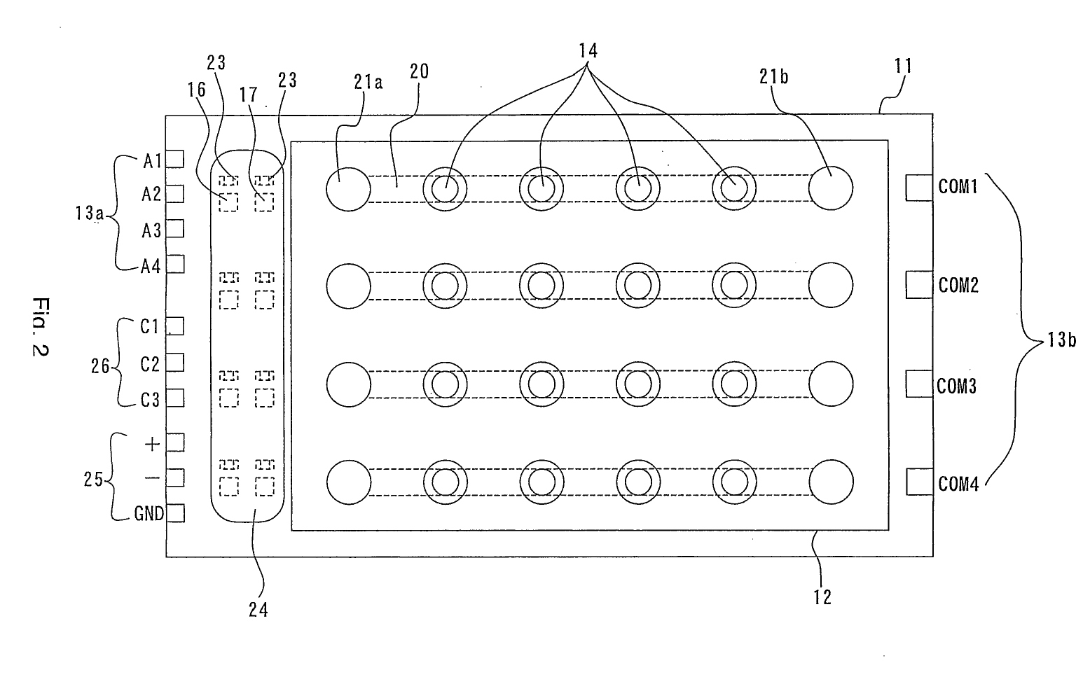

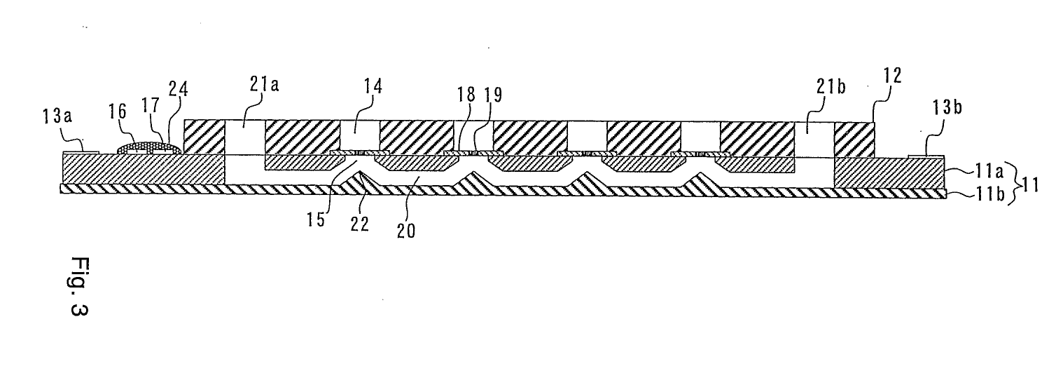

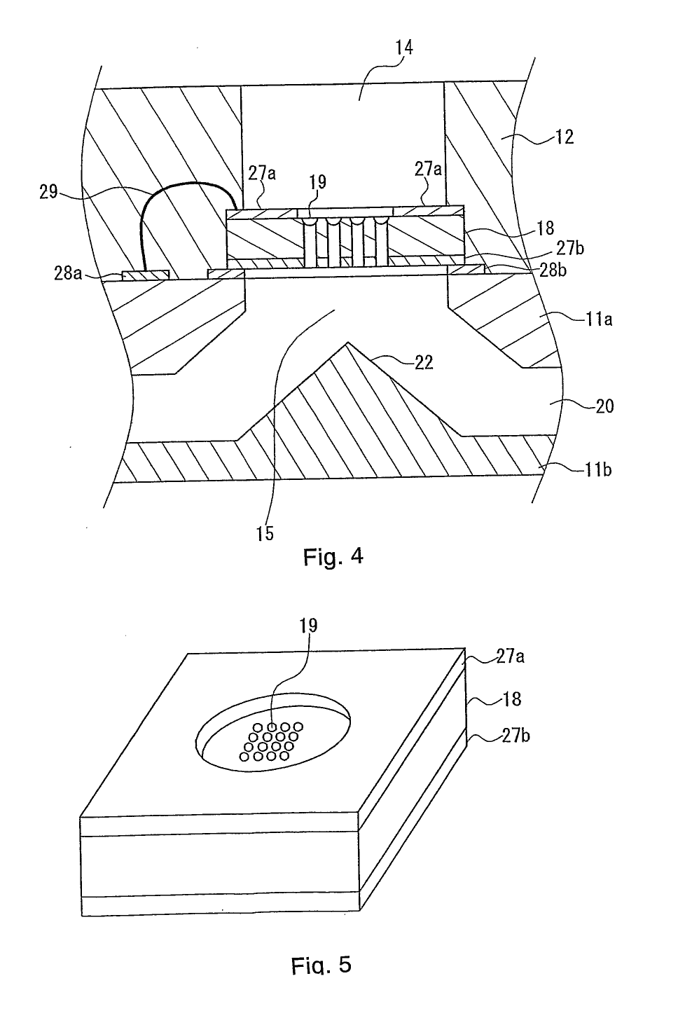

FIGS. 1, 2, 3 and 4 show a cellular potential measurement container according to one example of the present invention. FIG. 1 is a perspective view of the cellular potential measurement container, FIG. 2 is a plan view of the same, FIG. 3 is a sectional view of the same, taken in the arrow direction of line A-A in FIG. 1, and FIG. 4 is a partially enlarged sectional view of the sectional view of FIG. 3. In these drawings, the same elements are given the same reference numerals.

As shown in the drawings, in the cellular potential measurement container according to the present example, a top plate 11a is arranged on a bottom plate 11b, thus forming a container main body plate 11, and a resin portion 12 is arranged on the container main body plate 11. The container main body plate 11 has a rectangular plate shape, and the resin portion 12 has a rectangular plate shape whose length is shorter than that of the container main body plate 11. Thus, the surface of the container main body plate 11 is exposed at both end portions in its longitudinal direction. Inside the container main body plate 11, four second solution channels 20 are formed so as to extend in the longitudinal direction of the container main body plate 11. Above each of the second solution channels 20, four holes are formed so as to communicate with the channel, and an interior of each of the holes serves as a second solution reservoir 15. Partition substrates 18 are arranged on the surface of the container main body plate 11 so as to cover the holes, respectively. At portions corresponding to the second solution reservoirs 15 in the second solution channels 20, triangular protruding portions 22 are provided, respectively. The resin portion 12 has holes formed at positions corresponding to the respective second solution reservoirs 15 and positions corresponding to both ends of the respective second solution channels 20. The interiors of the holes provided at the positions corresponding to the second solution reservoirs 15 serve as first solution reservoirs 14, and the interiors of the holes provided at the positions corresponding to both the ends of the respective second solution channels 20 serve as second solution inlets 21a and second solution outlets 21b. The partition substrate 18 has a plurality of through holes 19. As shown in the sectional view of FIG. 4, on a surface of the partition substrate 18 on the first solution reservoir 14 side, a first electrode 27a is arranged so that a first solution can come into contact with the first electrode 27a. On a surface of the partition substrate 18 on the second solution reservoir 15 side (i.e., the rear surface of the partition substrate 18), a second electrode 27b is arranged so that a second solution can come into contact with the second electrode 27b. The first solution reservoir 14, the second solution reservoir 15, the partition substrate 18, the first electrode 27a, and the second electrode 27b constitute a single measurement unit. In the cellular potential measurement container according to the present example, four measurement units are arranged in series along the longitudinal direction of the container main body plate 11, and four rows of the four measurement units are arranged in parallel along the width direction of the container main body plate 11. A first wiring pattern 28a and a second wiring pattern 28b are formed on the surface of the container main body plate 11. The first wiring pattern 28a is connected to one end of a conductive wire 29 at its end portion. The other end of the conductive wire 29 is connected to the first electrode 27a. In the cellular potential measurement container according to the present example, the first wiring pattern 28a and the conductive wire 29 constitute a first wiring. Furthermore, in the cellular potential measurement container according to the present example, the second wiring pattern 28b serves as a second wiring, and the second electrode 27b is located on the second wiring pattern 28b, whereby they are connected electrically to each other. The first wiring pattern 28a, the conductive wire 29, and the second wiring pattern 28b are encapsulated with the resin portion 12. In the cellular potential measurement container according to the present example, four second measurement terminals 13b (COM1, COM2, COM3, COM4) are arranged at one end portion (the upper or right end portion in FIGS. 1 to 3) on the surface of the container main body plate 11, and four first measurement terminals 13a (A1, A2, A3, A4), three switching signal input terminals 26 (C1, C2, C3), and one set of power supply terminals 25 (+, −, GND) are arranged at the other end portion (the lower or left end portion in FIGS. 1 to 3) on the surface of the container main body plate 11. At the other end portion on the surface of the container main body plate 11, four electric signal amplifying devices 16 (amplifiers) and four switching devices 17 (multiplexers) are arranged between the above-described three types of terminals (13a, 26, 25) and the resin portion 12. Reference numeral 23 denotes a resistor constituting the electric signal amplifying device 16 or the switching device 17. The electric signal amplifying devices 16, the switching devices 17, and the resistors 23 are encapsulated with an encapsulation resin 24. In the cellular potential measurement container according to the present example, a single measurement group is constituted by the four measurement units arranged in series, one of the electric signal amplifying devices 16, one of the switching devices 17, and one of the first measurement terminals 13a (e.g., A1), and one of the second measurement terminals 13b (e.g., COM1), and the cellular potential measurement container according to the present example includes four such measurement groups in total. Note here that the electric signal amplifying device 16 is a voltage signal amplifying device when the cellular potential measurement container measures a voltage signal of cells and is a current signal amplifying device when the cellular potential measurement container measures a current signal of cells.

The material used for forming the container main body plate 11 (the top plate 11a and the bottom plate 11b) is not particularly limited, and can be, for example, an organic resin material such as polystyrene (PS), polycarbonate (PC), polyethylene terephthalate (PET), cycloolefin polymer (COP), or cycloolefin copolymer (COC) or an inorganic material such as glass, quartz, or ceramic. The size of the container main body plate 11 also is not particularly limited. When the container main body plate 11 has a rectangular plate shape, the size thereof may be 84 to 86 mm in length×127 to 129 mm in width×1 to 5 mm in thickness, for example. The thickness of the top plate 11a is, for example, 0.5 to 4.5 mm, and the thickness of the bottom plate 11b is, for example, 5 to 4.5 mm. The second solution reservoirs 15 and the second solution channels 20 of the container main body plate 11 can be formed by forming grooves and holes at predetermined positions on the top plate 11a and then adhering the top plate 11a and the bottom plate 11b to each other. The top plate 11a and the bottom plate 11b can be adhered to each other with an adhesive, for example. As the adhesive, it is possible to use a generally used adhesive such as, for example, an epoxy adhesive, an acrylic adhesive, and a silicon adhesive, but care should be taken so as to prevent the adhesive from being dissolved in the solution during use to influence the cell activity. Another example of the method of adhering the plates is a welding method that is applicable when the top plate 11a and the bottom plate 11b are formed of a thermoplastic resin (e.g., polystyrene). According to the welding method, bonding surfaces of the top plate 11a and the bottom plate 11b are melted using a laser beam, ultrasonic energy, or the like and then bonded to each other, thus achieving firm bonding without using an adhesive.

The material used for forming the resin portion 12 is not particularly limited, and the same materials used for forming the top plate and the bottom plate, such as PS, PC, PET, COP, and COC, can be used, for example. The size of the resin portion 12 is not particularly limited. When the resin portion 12 has a rectangular plate shape, the size thereof may be 70 to 86 mm in length×110 to 129 mm in width×3 to 10 mm in thickness, for example. The first solution reservoirs 14 can be formed by providing holes at predetermined positions of the resin portion. The resin portion 12 can be formed by, for example, a resin molding method such as transfer molding.

Although the cellular potential measurement container according to the present example has sixteen measurement units, the present invention is not limited thereto. For example, the cellular potential measurement container may have 24 to several hundred measurement units, preferably the same number of measurement units as that of wells included in a standardized microtiter plate, e.g., 24, 96, or 384. Examples of the first solution include a physiological salt solution containing NaCl as a main component, which generally is referred to as an extracellular fluid, but various changes can be made in the extracellular fluid depending on the type of cells to be subjected to the measurement. Examples of the second solution include a physiological salt solution containing KCl as a main component, which generally is referred to as an intracellular fluid, but various changes can be made in the intracellular fluid depending on the type of the cells as in the case of the extracellular fluid. Preferably, the second solution contains a substance that causes a hole to be formed in a cell membrane. As such a substance, nystatin can be used, for example.

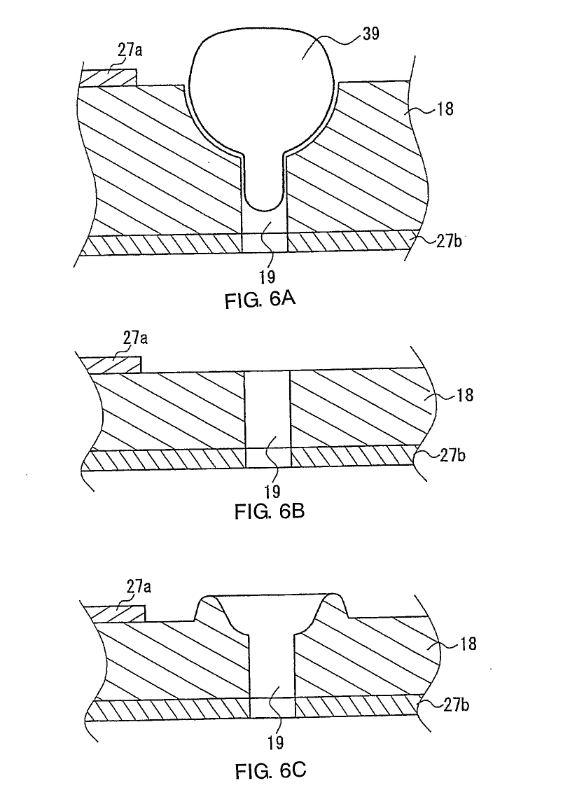

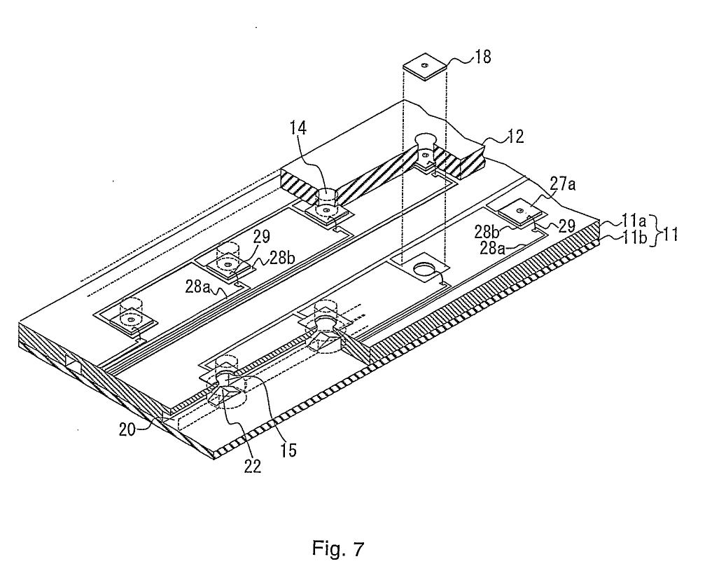

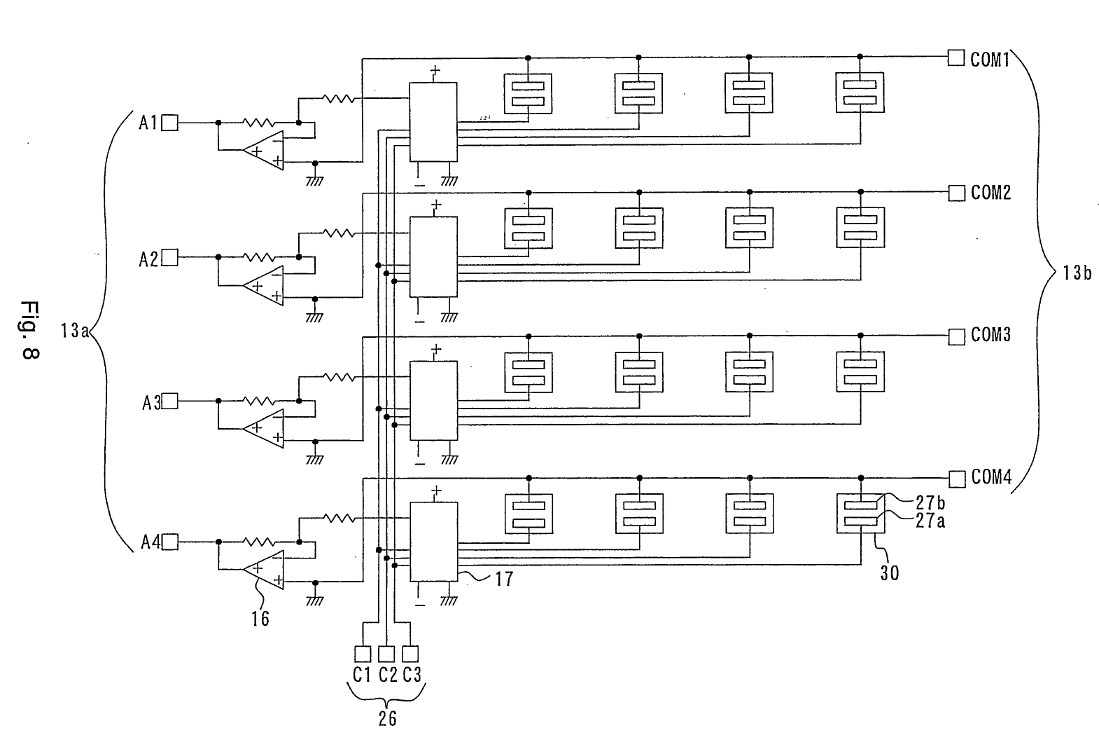

One example of the partition substrate 18 used in the cellular potential measurement container according to the present example is shown in the perspective view of FIG. 5. In FIG. 5, the same elements as those in FIGS. 1 to 4 are given the same reference numerals. As shown in FIG. 5, the partition substrate 18 has a square plate shape, and sixteen through holes 19 are arranged in the form of a square of 4×4 at a central portion on the surface of the partition substrate 18. The first electrode 27a is formed so as to surround the through holes 19 on the surface of the partition substrate 18, and the second electrode 27b is formed on the rear surface of the partition substrate 18. An opening of the through hole 19 at the end portion on the first solution reservoir 14 side may be substantially semispherical as shown in the sectional views of FIGS. 4 and 6A. When the opening has such a shape, a cell 39 can be held reliably as shown in FIG. 6A, thus allowing a tight electrical seal to be achieved. In FIG. 6, the same elements as those in FIGS. 1 to 5 are given the same reference numerals. It is to be noted here that the shape of the through hole 19 is not particularly limited. For example, as shown in FIG. 6B, the inner diameter of the through hole 19 may be constant along the axial direction, or alternatively, as shown in FIG. 6C, the through hole 19 may have a shape such that a portion around the opening on the first solution reservoir 14 side protrudes upward.

The material used for forming the partition substrate 18 is not particularly limited. For example, not only inorganic materials such as silicon, quartz, and glass but also organic resin materials such as PC, PET, polyimide (PI), and polydimethylsiloxane (PDMS) can be used as the material used for forming the partition substrate 18. The size of the partition substrate 18 is not particularly limited. When the partition substrate 18 has a square plate shape, the size thereof may be 0.3 to 3.0 mm in length×0.3 to 3.0 mm in width×0.001 to 1.0 mm in thickness, for example. The number of the through holes 19 is not limited to sixteen described above, and may be, for example, 1 to 100, preferably 2 to 50, and more preferably 3 to 10.The inner diameter of the through hole is not particularly limited as long as it is smaller than the maximum diameter of the cell to be subjected to the measurement, and may be, for example, 0.5 to 10 μm.

The material used for forming the first electrode and second electrode is not particularly limited, and may be, for example, silver-silver chloride, gold, or platinum. The thickness of the first electrode and the second electrode is, for example, 0.1 to 100 μm. The first electrode and the second electrode can be formed using any of the above-described materials by, for example, an ordinary thin film-forming method such as vacuum evaporation or sputtering or an electrode-forming method such as printing or plating.

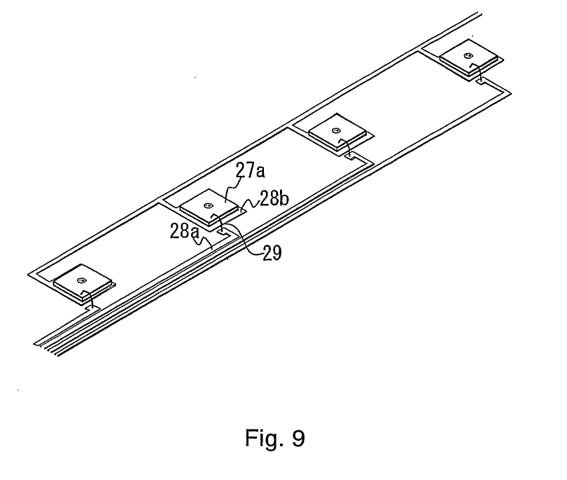

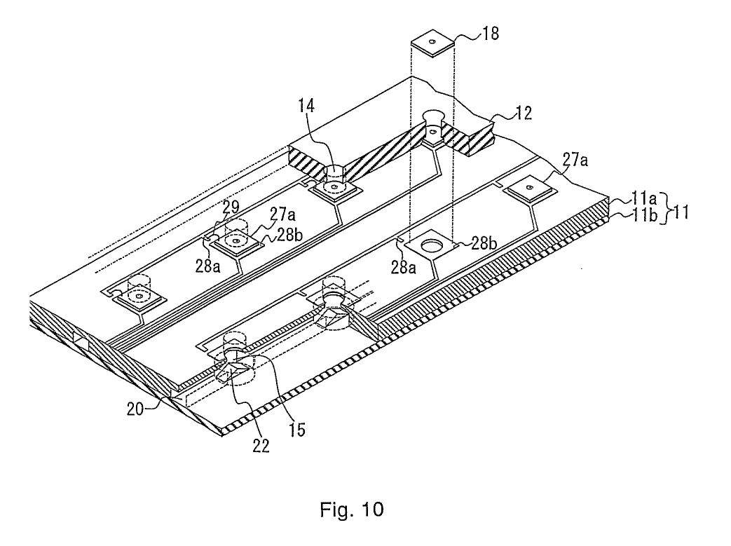

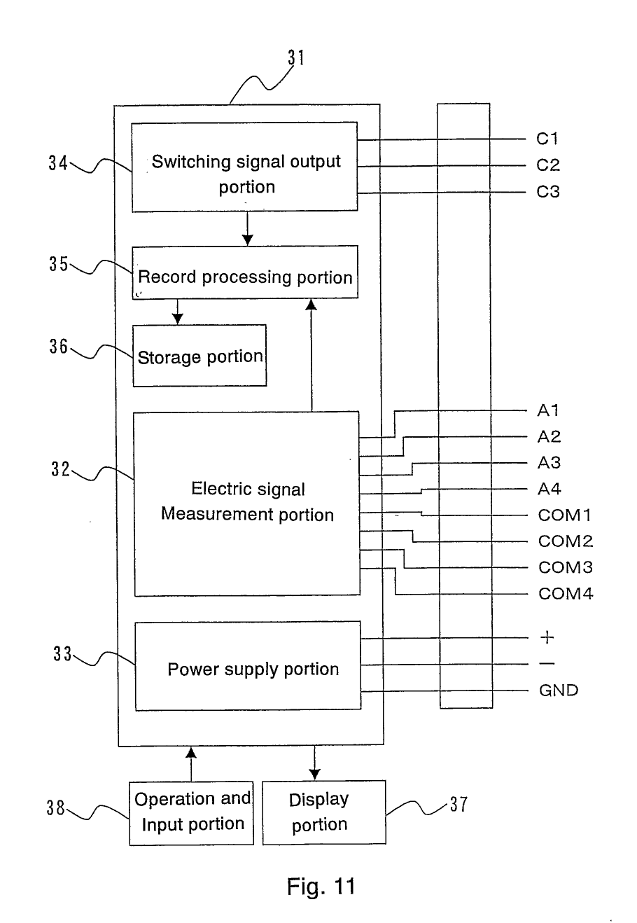

One example of the connection between the first and second electrodes and the first and second wirings in the cellular potential measurement container according to the present example will be described with reference to the partially sectional perspective view of FIG. 7 and the perspective view of FIG. 9. In FIGS. 7 and 9, the same elements as those in FIGS. 1 to 6 are given the same reference numerals. As shown in the drawings, in the cellular potential measurement container according to the present example, first wiring patterns 28a and a second wiring pattern 28b are formed on the surface of the container main body plate 11. In FIGS. 7 and 9, four first wiring patterns 28a are formed in each of the measurement groups, and an end portion of each of the first wiring patterns 28a is connected to one end of the conductive wire 29. The other end of the conductive wire 29 is connected to the first electrode 27a. The first wiring patterns 28a and the conductive wires 29 constitute the first wiring, and the first wiring is connected to one first measurement terminal (not shown) via a switching device (not shown). On the other hand, as shown in the drawings, the second wiring pattern 28b has a shape such that four wiring patterns are branched from a single linear wiring pattern, and an end portion of each of the branched wiring patterns is formed so as to be a bonding pad. A second electrode (not shown) is arranged on the bonding pad and is connected thereto. The second wiring pattern serves as the second wiring, and the second wiring is connected to a second measurement terminal through a common wiring structure. Next, a wiring pattern that is different from those shown in FIG. 7 and FIG. 9 is shown in the partially sectional perspective view of FIG. 10. As shown in FIG. 10, a first wiring pattern 28a includes a linear wiring pattern extending along the longitudinal direction of the container main body plate 11 and four end portions branched from the linear wiring pattern. Each of the four end portions of the first wiring pattern 28a is connected to one end of a conductive wire 29, and the other end of the conductive wire 29 is connected to each of the first electrodes 27a. The first wiring pattern 28a and the conductive wires 29 constitute the first wiring of the present invention. According to this wiring structure, the first wiring connected to the first electrode 27a is connected to the second measurement terminal through a common wiring structure. On the other hand, the second wiring pattern 28b includes a bonding pad and a linear wiring pattern extending from the bonding pad in the longitudinal direction of the container main body plate 11. In this wiring structure, the second wiring pattern 28b corresponds to the second wiring of the present invention, and, although not shown in the drawings, the second electrode 27b to be connected to the second wiring can be switched from one to another by a switching device, and the second electrodes 27b are connected to the first measurement terminal via the switching device.

The material used for forming the first wiring pattern and the second wiring pattern is not particularly limited, and a material used for forming a wiring of a printed circuit board, such as copper or a copper alloy, can be used, for example. The first wiring pattern and the second wiring pattern can be formed using any of the above-described materials by a known method for forming a wiring of a printed circuit board, such as photolithography or printing. The material used for forming the conductive wire can be, for example, gold or an aluminum-based metal. The conductive wire is bonded to the end portion of the first wiring pattern 28a and the first electrode 27a by, for example, wire bonding that is used in assembling a semiconductor package. On the surface of the end portion of the first wiring pattern 28a and the surface of the first electrode 27a to which the wire is to be bonded, a plated layer (not shown) may be formed to achieve better bonding to the wire, for example.

One example of the wiring structure in the cellular potential measurement container according to the present example is shown in the circuit diagram of FIG. 8. In FIG. 8, the same elements as those in FIGS. 1 to 7 are given the same reference numerals. As shown in FIG. 8, in the cellular potential measurement container according to the present example, four measurement units 30 are provided with respect to one second solution channel in each measurement group. Furthermore, one first measurement terminal 13a, one second measurement terminal 13b, one electric signal amplifying device 16, and one switching device 17 are provided with respect to one measurement group. In each measurement group, four first electrodes 27a of the four measurement units 30 are connected to one electric signal amplifying device 16 via one switching device 17, and the electric signal amplifying device 16 is connected to one first measurement terminal 13a (A1, A2, A3, or A4). Furthermore, four second electrodes 27b of the four measurement units are connected to one second measurement terminal 13b (COM1, COM2, COM3 or COM4) through a common wiring structure. The switching device 17 of each measurement group is connected to three switching signal input terminals 26 (C1, C2, and C3). In accordance with a signal input from the switching signal input terminals 26, the measurement unit 30 to be used in the measurement is selected, and the first electrode 27a of the select measurement unit 30 is connected to the first measurement terminal 13a. It is to be noted that the present invention is not limited to this wiring structure, and may have a wiring structure as shown in the circuit diagram of FIG. 20, in which the first electrode 27a is connected to one second measurement terminal 13b (COM1, COM2, COM3, or COM4) through a common wiring structure and the second electrode 27b is connected to one first measurement terminal 13a (A1, A2, A3 or A4) via the switching device 17 and the electric signal amplifying device 16. In FIG. 20, the same elements as those in FIGS. 1 to 7 are given the same reference numerals.

Next, one example of a cellular potential measurement device to be used with the cellular potential measurement container according to the present example will be described. One example of the configuration of the cellular potential measurement device is shown in the functional block diagram of FIG. 11. As shown in FIG. 11, the cellular potential measurement device includes a measurement device main body 31, a display portion 37, and an operation and input portion 38. The measurement device main body 31 includes an electric signal measurement portion 32, a power supply portion 33, a switching signal output portion 34, a record processing portion 35, and a storage portion 36. The electric signal measurement portion 32 can be connected to the first measurement terminals (A1, A1, A3, and A4) and the second measurement terminals (COM1, COM2, COM3, and COM4). The electric signal measurement portion 32 converts a signal (a voltage or a current) input from both the first and second measurement terminals into a digital signal at a predetermined sampling period and transmits the thus-obtained digital signal to the record processing portion 35. The power supply portion 33 can be connected to the power supply terminals (+, −, GND) and supplies an electric power to the electric signal amplifying device 16. The switching signal output portion 34 can be connected to the switching signal input terminals 26 (C1, C2, and C3). The switching signal output portion 34 transmits a signal to the switching device 17 and selects the measurement unit to be subjected to the measurement. Furthermore, the switching signal output portion 34 outputs information that identifies the selected measurement unit to the record processing portion 35. The record processing portion 35 stores the information transmitted from the switching signal output portion 34, i.e., the information that identifies the measurement unit, in the storage portion 36 in association with the digitized signal transmitted from the electric signal measurement portion 32. Operations such as input of a switching signal are carried out through the operation and input portion 38 or alternatively, they are carried out automatically according to a switching pattern that has been set in advance. As the operation and input portion, an ordinary operation and input device such as a keyboard or a mouse is used, for example. The measurement result is not only stored in the storage portion 36 but also is displayed in the display portion 37. As the display portion 37, a generally used display can be used, for example.

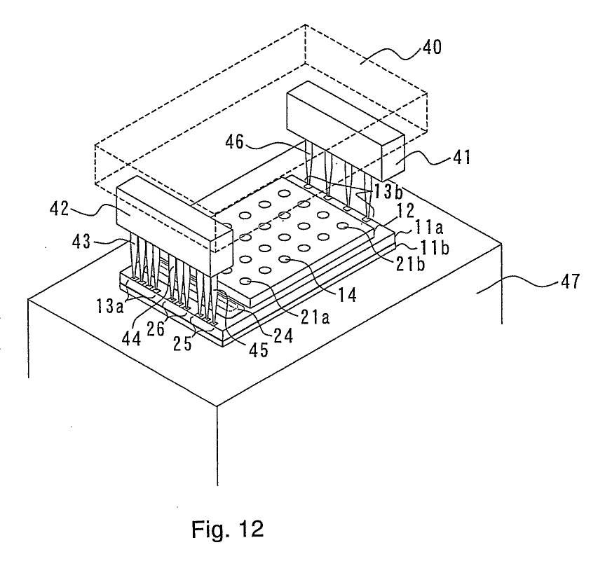

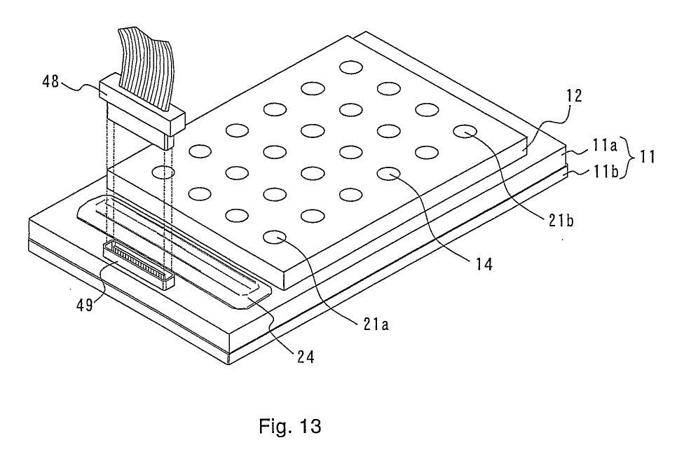

The cellular potential measurement device has connection probes to be connected to the respective terminals of the cellular potential measurement container. In the following, the configuration of the probes will be described with reference to the perspective view of FIG. 12. In FIG. 12, the same elements as those in FIG. 1 to 11 are given the same reference numerals. As shown in FIG. 12, the cellular potential measurement device includes a probe head main body 40, a first probe holding portion 42, and a second probe holding portion 41. The first probe holding portion 42 includes probes 43 to be connected to the first measurement terminals 13a, probes 45 to be connected to the power supply terminals 25, and probes 44 to be connected to the switching signal input terminals 26. The second probe holding portion 41 includes probes 46 to be connected to the second measurement terminals 13b. The probe head main body 40 can be moved up and down by a lifting mechanism that is not shown in FIG. 12. Accordingly, the connection between the probes (43, 44, 45, 46) and the terminals (13a, 13b, 25, 26) of the cellular potential measurement container can be achieved by moving down the probe head main body 40 using the lifting mechanism with the cellular potential measurement container being placed on the measurement stand 47.

Next, an example of a method of measuring a cellular potential using the cellular potential measurement container according to the present example will be described. First, cells to be subjected to the measurement are provided and then are dispersed in a first solution. The first solution in which the cells are dispersed is poured into the first solution reservoirs 14 so that the cells are held in openings at one end (openings on the first solution reservoir 14 side) of the respective through holes 19. The cells can be held by applying suction to the cells through the through holes 19, the second solution reservoirs 15, the second solution channels 20, and the second solution inlets 21a (or the second solution outlets 21b) with a suction pump (not shown). At this time, the cells are held so that a tight electrical seal is attained. On the other hand, through the second solution inlets 21a, the second solution is introduced into the second solution channels 20 and further into the second solution reservoirs 15. At this time, the second solution is caused to flow into the through holes 19 due to the triangular protruding portions 22. Then, with the cells to be subjected to the measurement being held in the openings of the through holes 19, the cellular potential is measured. The measurement of the cellular potential is carried out by connecting a cellular potential measurement device that is provided separately to the cellular potential measurement container according to the present example.

After the preparation of the cellular potential measurement is completed through the above-described procedure, the cellular potential is measured in the following manner. First, the cellular potential measurement container is placed on the measurement stand 47 of the cellular potential measurement device, and the probe head main body 40 is moved down so as to bring the probes 43, 44, 45, and 46 into contact with the first measurement terminals 13a, the switching signal input terminals 26, the power supply terminals 25, and the second measurement terminals 13b, respectively. Thus, the cellular potential measurement device and the cellular potential measurement container form an integrated circuit, so that the electric signal amplifying device 16 and the switching device 17 can be operated when an electric power is supplied thereto by the power supply portion 33.

Next, a switching signal is transmitted to the switching device 17 from the switching signal output portion 34 of the cellular potential measurement device. Then, in accordance with the instruction by the switching signal, the switching device 17 selects the measurement unit and connects the first electrode 27a of this measurement unit to the first measurement terminal. Thereafter, an electric signal detected by the first electrode and the second electrode of the selected measurement unit is amplified by the electric signal amplifying device and then is measured by the electric signal measurement portion 32 of the measurement device. The electric signal measured by the electric signal measurement portion 32 is converted into a digital signal at a predetermined sampling period, and the thus-obtained digital signal is transmitted to the storage portion 36 via the record processing portion 35 and is stored therein. In the above-described manner, the cellular potential is measured by switching the measurement unit to be used in the measurement from one to another successively by the switching device. The switching of the measurement unit to be used in the measurement may be carried out manually using the operation and input portion 38 of a keyboard or the like. Alternatively, it may be carried out automatically based on the predetermined switching order (switching pattern) that has been stored in the storage portion 36 in advance.

Examples of the method of connecting the measurement device and the cellular potential measurement container according to the present example include, in addition to the above-described method using the connection probes, a method of using a connector as shown in FIG. 13. In FIG. 13, the same elements as those in FIGS. 1 to 12 are given the same reference numerals. More specifically, in the cellular potential measurement container according to the present example, a connector terminal 49 is provided at one end portion on the surface of the container main body plate 11, and the first measurement terminals, the second measurement terminals, the power supply terminals, and the switching signal input terminals are provided inside the connector terminal 49. On the other hand, the cellular potential measurement device (not shown) is connected to a connector terminal 48 through a wiring. The cellular potential measurement device and the cellular potential measurement container according to the present example are connected to each other by connecting the connector terminals 48 and 49 to each other.

In the present invention, the cellular potential may be measured using cells in a natural state. Also, the cellular potential may be measured in the presence of a chemical substance or a pharmaceutical-candidate substance. Besides the above, the cellular potential may be measured in the presence of light, heat, an electromagnetic wave, a pressure, or a mechanical force.

### EXAMPLE 2

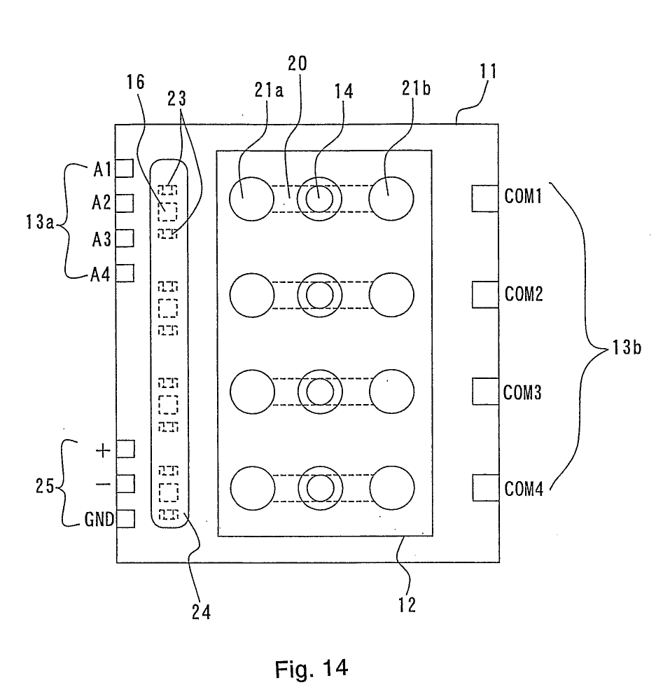

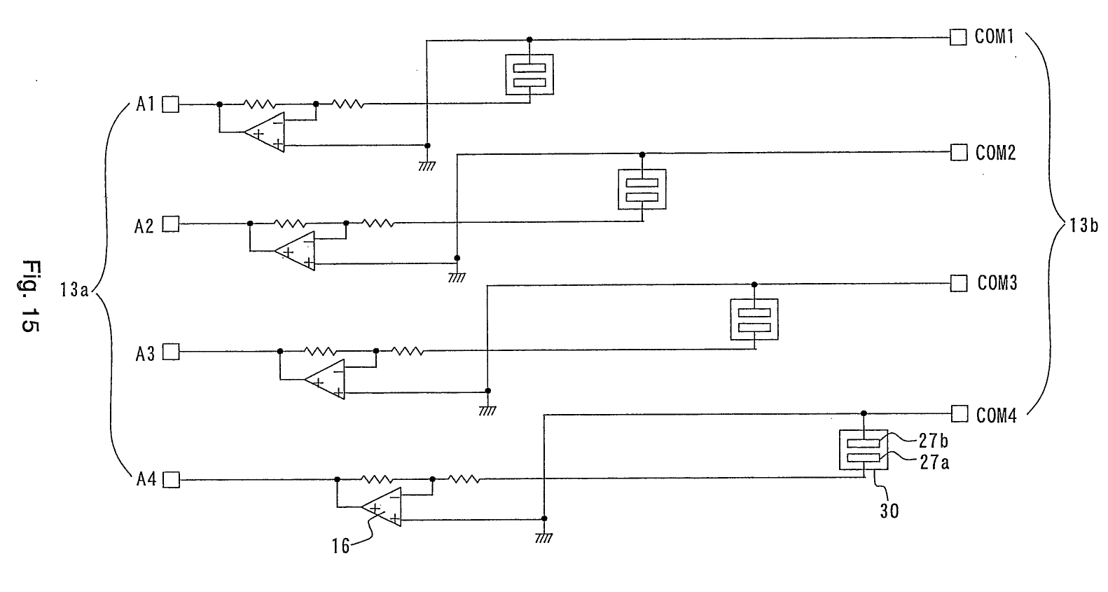

Next, a cellular potential measurement container according to another example of the present invention will be described with reference to FIGS. 14 and 15. FIG. 14 is a plan view of the cellular potential measurement container according to the present example, and FIG. 15 is a circuit diagram showing the cellular potential measurement container according to the present example. In FIGS. 14 and 15, the same elements as those in FIGS. 1 to 13 are given the same reference numerals.

As shown in FIG. 14, the cellular potential measurement container according to the present example has the same configuration as the cellular potential measurement container according to Example 1, except that one measurement unit is formed with respect to one second solution channel 20 and no switching device is used. More specifically, as shown in FIG. 14, in the cellular potential measurement container according to the present example, a resin portion 12 is provided on a container main body plate 11, and first solution reservoirs 14 are formed on the resin portion 12. Below each of the first solution reservoir 14, a second solution reservoir (not shown) is formed inside the container main body plate 11 via a partition substrate (not shown) having a first electrode and a second electrode, thus constituting a single measurement unit. The second solution reservoirs communicate with the second solution channels 20, and openings at one end of the respective second solution channels 20 serve as second solution inlets 21a, while openings at the other end of the respective second solution channels 20 serve as second solution outlets 21b. Furthermore, four first measurement terminals 13a (A1, A2, A3 and A4) and three power supply terminals 25 (+, −, GND) are arranged at one end portion (the left end portion in FIG. 14) on the surface of the container main body plate 11, and four second measurement terminals 13b (COM1, COM2, COM3, and COM4) are arranged at the other end portion (the right end portion in FIG. 14) on the surface of the container main body plate 11. As shown in FIG. 15, the second electrodes 27b of the respective measurement units 30 are connected to the second measurement terminals 13b on a one-to-one basis through individual wirings, and the first electrodes 27a of the respective measurement units 30 are connected to the first measurement terminals 13a via electric signal amplifying devices 16 on a one-to-one basis through individual wirings. When the number of the measurement units is small as in the present example, it is possible to simplify the circuit configuration by omitting a switching device. This eliminates the necessity of providing a switching signal output portion in a cellular potential measurement device, which is advantageous in terms of cost.

### EXAMPLE 3

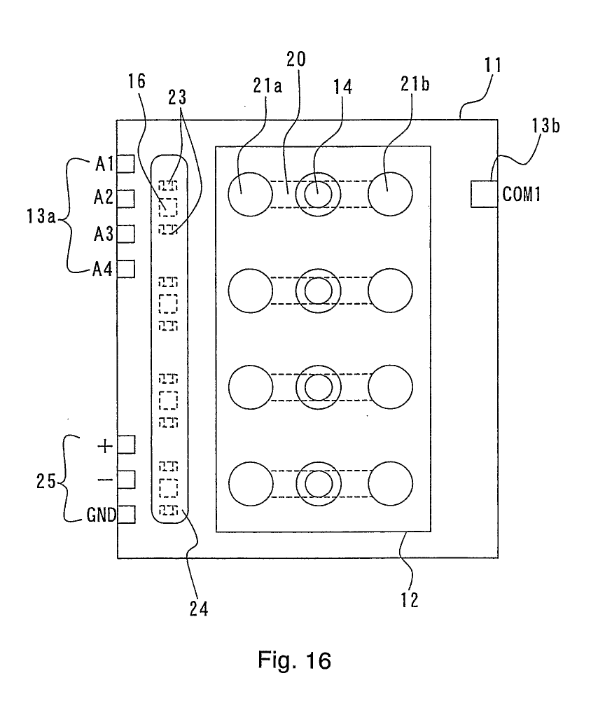

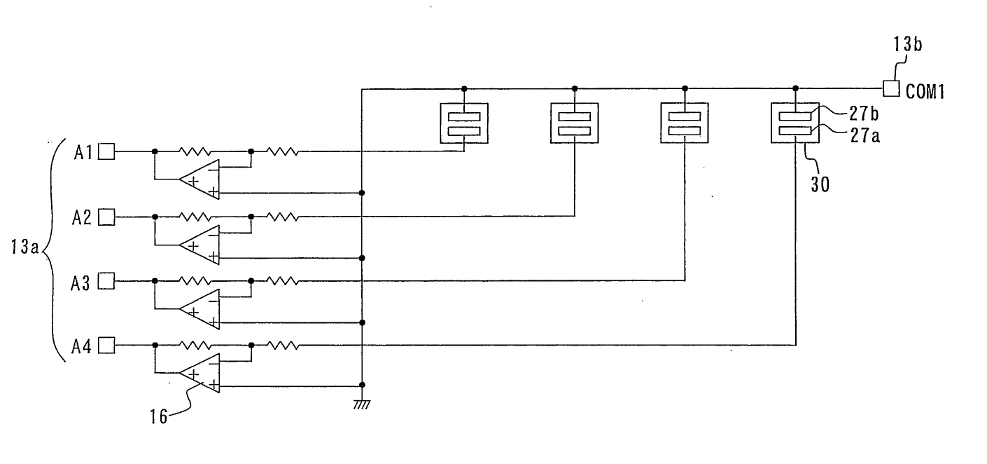

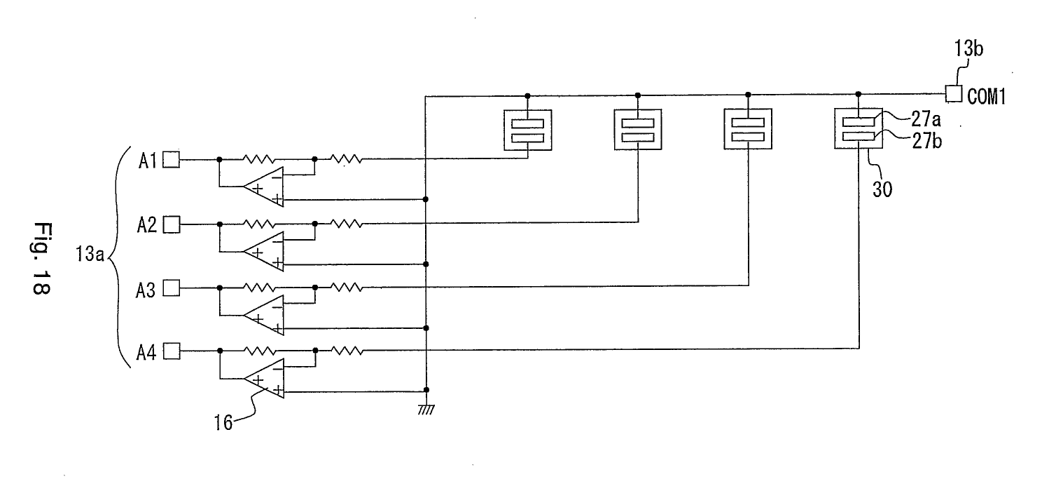

Next, a cellular potential measurement container according to still another example of the present invention will be described with reference to FIGS. 16 and 17. FIG. 16 is a plan view of the cellular potential measurement container according to the present example, and FIG. 17 is a circuit diagram showing the cellular potential measurement container according to the present example. In FIGS. 16 and 17, the same elements as those in FIGS. 1 to 15 are given the same reference numerals.

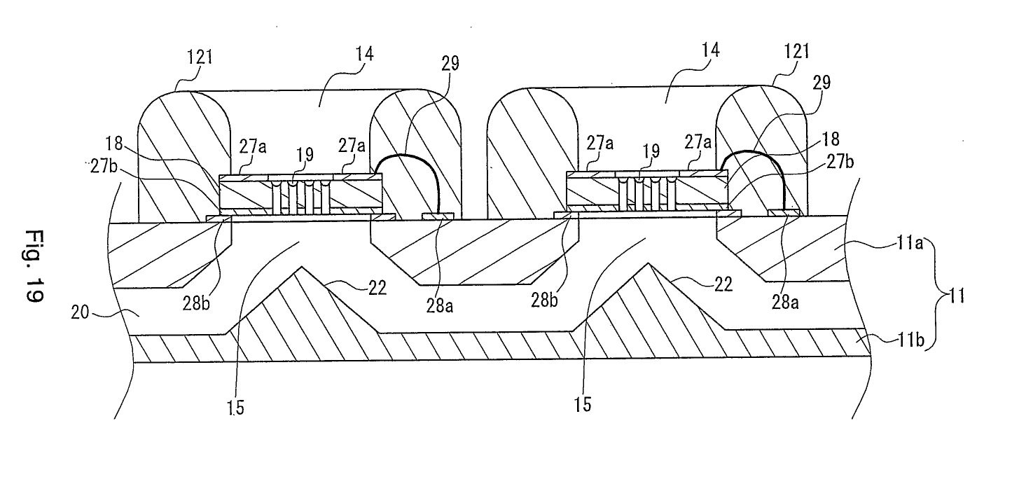

As shown in FIG. 16, the cellular potential measurement container according to the present example has the same configuration as the cellular potential measurement container according to Example 2, except that the second electrodes 27b of the respective measurement units are connected to a single second measurement terminal 13b through a common wiring structure. More specifically, as shown in FIG. 16, in the cellular potential measurement container according to the present example, a resin portion 12 is provided on a container main body plate 11, and first solution reservoirs 14 are formed on the resin portion 12. Below each of the first solution reservoir 14, a second solution reservoir (not shown) is formed inside the container main body plate 11 via a partition substrate (not shown) having a first electrode and a second electrode, thus constituting a single measurement unit. The second solution reservoirs communicate with second solution channels 20, and openings at one end of the respective second solution channels 20 serve as second solution inlets 21a, while openings at the other end of the respective second solution channels 20 serve as second solution outlets 21b. Furthermore, four first measurement terminals 13a (A1, A2, A3 and A4) and three power supply terminals 25 (+, −, GND) are arranged at one end portion (the left end portion in FIG. 16) on the surface of the container main body plate 11, and one second measurement terminal 13b (COM1) is arranged at the other end portion (the right end portion in FIG. 16) on the surface of the container main body plate 11. As shown in FIG. 17, the second electrodes 27b of the respective measurement units 30 are connected to the single second measurement terminal 13b through a common wiring structure, and the first electrodes 27a of the respective measurement units 30 are connected to the first measurement terminals 13a via electric signal amplifying devices 16 on a one-to-one basis through individual wirings. By employing the wiring structure as in the present example, it becomes possible to simplify the circuit configuration. It is to be noted that, in the present example, the electrodes to which the common wiring structure is applicable are not limited to the second electrodes, but the first electrodes may be connected to the single second measurement terminal through a common wiring structure. This alternative example will be described based on the circuit diagram of FIG. 18. In FIG. 18, the same elements as those in FIGS. 1 to 17 are given the same reference numerals. As shown in FIG. 18, second electrodes 27b of respective measurement units 30 are connected to first measurement terminals 13a via electric signal amplifying devices 16 on a one-to-one basis through individual wirings, and first electrodes 27a of the respective measurement units 30 are connected to a single second measurement terminal 13b through a common wiring structure.

### EXAMPLE 4

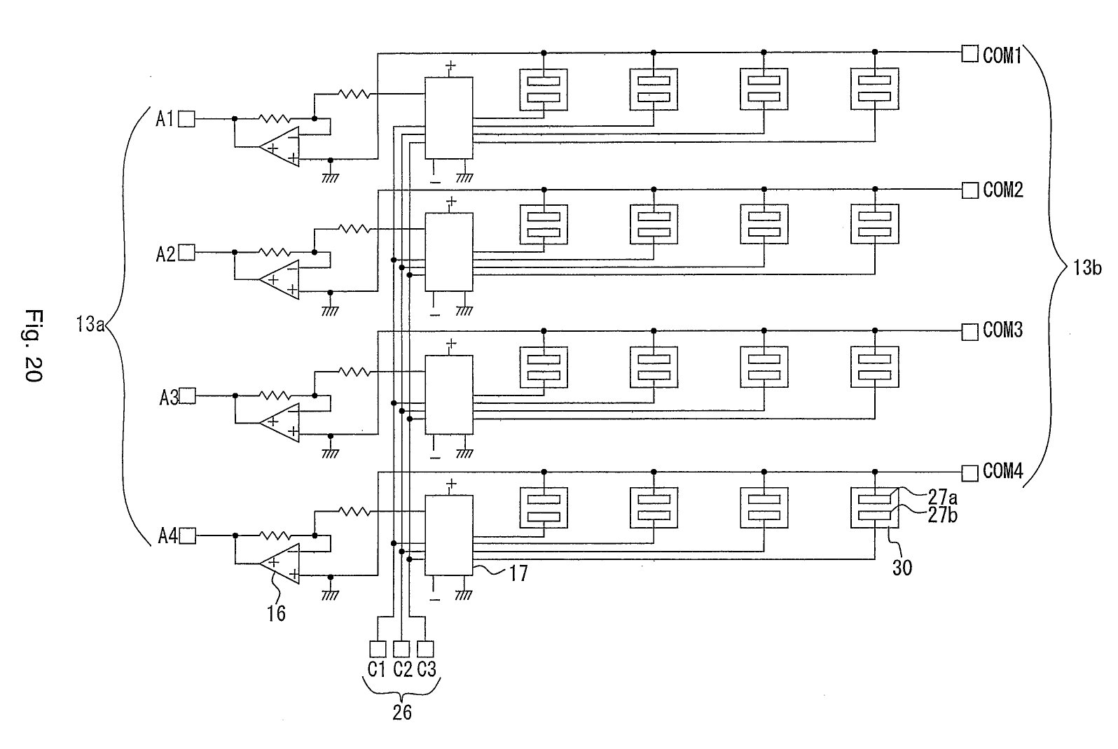

Next, a cellular potential measurement container according to still another example of the present invention will be described with reference to the sectional view of FIG. 19. In FIG. 19, the same elements as those in FIGS. 1 to 18 are given the same reference numerals.

The cellular potential measurement container according to the present example has the same configuration as the above-described cellular potential measurement containers according to Example 1 etc., except that the resin portion is formed with respect to each one of the plurality of measurement units. As shown in FIG. 19, in the cellular potential measurement container according to the present example, a container main body plate 11 is formed of a bottom plate 11b and a top plate 11a, and second solution channels 20, protruding portions 22, and second solution reservoirs 15 are formed inside the container main body plate 11. A partition substrate 18 is arranged at a position corresponding to each of the second solution reservoirs 15 on the surface of the container main body plate 11. The partition substrate 18 has a plurality of through holes 19. A first electrode 27a is formed on the surface (the upper surface in FIG. 19) of the partition substrate 18, and a second electrode 27b is formed on the rear surface (the lower surface in FIG. 19) of the partition substrate 18. A first wiring pattern 28a is formed on the surface of the container main body plate 11, and the first wiring pattern 28a is connected to the first electrode 27a via a conductive wire 29. Furthermore, a second electrode pattern 28b is formed on the surface of the container main body plate 11, and the second electrode 27b is located on a part of the second electrode pattern 28b, whereby they are connected to each other. An edge portion of each of the partition substrate 18 is covered with a resin portion 121, and an interior of the resin portion 121 serves as a first solution reservoir 14. Furthermore, a part of the first wiring pattern 28a and the second wiring pattern 28b and the conductive wire 29 are encapsulated with the resin portion 121. By forming the resin portion individually with respect to each of the measurement units as in the present example, the cellular potential measurement container sufficiently can cope with the demand for still higher densification caused by an increase in the number of cells to be subjected to measurement.

### INDUSTRIAL APPLICABILITY

As specifically described above, since the cellular potential measurement container of the present invention has the electric signal amplifying device, it is possible to suppress the noise. Therefore, even when the number of the cells to be subjected to the measurement is increased, for example, in order to perform high-speed screening and the wiring for transmitting an electric signal thus becomes long, it is possible to suppress the noise efficiently so that the cellular potential measurement can be carried out with higher accuracy than in the prior art. Therefore, the cellular potential measurement container according to the present invention is useful in all the fields in which cellular potential measurement is performed, and it can be used effectively in the study of cell electrophysiology and the development of pharmaceuticals, for example.

1. A cellular potential measurement container comprising:
a measurement unit that comprises a first solution reservoir, a second solution reservoir, a partition substrate, a first electrode, and a second electrode;
a first measurement terminal; and
a second measurement terminal,
the measurement unit being configured so that the first solution reservoir and the second solution reservoir are partitioned with the partition substrate, the partition substrate has a through hole, a first end of the through hole is open toward the first solution reservoir while a second end of the through hole is open toward the second solution reservoir, the opening at the first end of the through hole can hold a cell, the first electrode is arranged so that a first solution can come into contact with the first electrode, and the second electrode is arranged so that a second solution can come into contact with the second electrode,
wherein the cellular potential measurement container further comprises an electric signal amplifying device and a power supply terminal, the power supply terminal is connected electrically to the electric signal amplifying device, and one of the first electrode and the second electrode is connected electrically to the first measurement terminal via the electric signal amplifying device while the other one of the first electrode and the second electrode is connected electrically to the second measurement terminal.

2. The cellular potential measurement container according to claim 1, comprising a plurality of said measurement units.

3. The cellular potential measurement container according to claim 2, comprising as many electric signal amplifying devices, first measurement terminals, and second measurement terminals as the measurement units,
wherein the first electrodes are connected to the first measurement terminals via the electric signal amplifying devices on a one-to-one basis, and the second electrodes are connected to the second measurement terminals on a one-to-one basis.

4. The cellular potential measurement container according to claim 1, comprising a plurality of said measurement units, a plurality of electric signal amplifying devices, a plurality of first measurement terminals, and a single second measurement terminal,
wherein the first electrodes are connected to the first measurement terminals via the electric signal amplifying devices on a one-to-one basis, and the second electrodes are connected to the second measurement terminal through a common wiring structure.

5. The cellular potential measurement container according to claim 1, comprising a plurality of said measurement units, a plurality of electric signal amplifying devices, a plurality of first measurement terminals, and a single second measurement terminal,
wherein the second electrodes are connected to the first measurement terminals via the electric signal amplifying devices on a one-to-one basis, and the first electrodes are connected to the second measurement terminal through a common wiring structure.

6. A cellular potential measurement container comprising:
a plurality of measurement units, each comprising a first solution reservoir, a second solution reservoir, a partition substrate, a first electrode, and a second electrode;
a first measurement terminal; and
a second measurement terminal,
each of the measurement units being configured so that the first solution reservoir and the second solution reservoir are partitioned with the partition substrate, the partition substrate has a through hole, a first end of the through hole is open toward the first solution reservoir while a second end of the through hole is open toward the second solution reservoir, the opening at the first end of the through hole can hold a cell, the first electrode is arranged so that a first solution can come into contact with the first electrode, and the second electrode is arranged so that a second solution can come into contact with the second electrode,
wherein the cellular potential measurement container further comprises an electric signal amplifying device, a power supply terminal, a switching device, and a switching signal input terminal, the power supply terminal and the electric signal amplifying device are connected electrically to each other, the switching device and the switching signal input terminal are connected electrically to each other, and one measurement group is constituted by the plurality of measurement units, the electric signal amplifying device, the switching device, the first measurement terminal, and the second measurement terminal, and
wherein, in the measurement group, the plurality of second electrodes are connected to the second measurement terminal through a common wiring structure, any one of the plurality of first electrodes is connected electrically to the first measurement terminal via the switching device and the electric signal amplifying device, and the first electrode to be connected electrically to the first measurement terminal is selected from the plurality of first electrodes by the switching device.

7. A cellular potential measurement container comprising:
a plurality of measurement units, each comprising a first solution reservoir, a second solution reservoir, a partition substrate, a first electrode, and a second electrode;
a first measurement terminal; and
a second measurement terminal,
each of the measurement units being configured so that the first solution reservoir and the second solution reservoir are partitioned with the partition substrate, the partition substrate has a through hole, a first end of the through hole is open toward the first solution reservoir while a second end of the through hole is open toward the second solution reservoir, the opening at the first end of the through hole can hold a cell, the first electrode is arranged so that a first solution can come into contact with the first electrode, and the second electrode is arranged so that a second solution can come into contact with the second electrode,
wherein the cellular potential measurement container further comprises an electric signal amplifying device, a power supply terminal, a switching device, and a switching signal input terminal, the power supply terminal and the electric signal amplifying device are connected electrically to each other, the switching device and the switching signal input terminal are connected electrically to each other, and one measurement group is constituted by the plurality of measurement units, the electric signal amplifying device, the switching device, the first measurement terminal, and the second measurement terminal, and
wherein, in the measurement group, the plurality of first electrodes are connected to the second measurement terminal through a common wiring structure, any one of the plurality of second electrodes is connected electrically to the first measurement terminal via the switching device and the electric signal amplifying device, and the second electrode to be connected electrically to the first measurement terminal is selected from the plurality of second electrodes by the switching device.

8. The cellular potential measurement container according to claim 6, comprising a plurality of said measurement groups.

9. The cellular potential measurement container according to claim 1, further comprising a second solution channel,
wherein one or a plurality of said measurement units are arranged above the second solution channel, the second solution reservoir communicates with the second solution channel, and an opening at one end of the second solution channel serves as an inlet for the second solution while an opening at the other end of the second solution channel serves as an outlet for the second solution.

10. The cellular potential measurement container according to claim 9, wherein flow direction control means for causing the second solution to flow toward the second solution reservoir is arranged at a position corresponding to the second solution reservoir in the second solution channel.

11. The cellular potential measurement container according to claim 10, wherein the flow direction control means is a protruding portion formed inside the second solution channel.

12. The cellular potential measurement container according to claim 1, comprising a plurality of said second solution channels,
wherein one or a plurality of said measurement units are formed above each of the second solution channels.

13. The cellular potential measurement container according to claim 1, wherein the second solution reservoir is arranged below the first solution reservoir.

14. The cellular potential measurement container according to claim 1, wherein the first electrode is arranged on a surface of the partition substrate on the first solution reservoir side, and the second electrode is arranged on a surface of the partition substrate on the second solution reservoir side.

15. The cellular potential measurement container according to claim 1, wherein the partition substrate has a plurality of said through holes.

16. A cellular potential measurement container comprising:
a container main body plate;
a resin portion;
a partition substrate;
a first electrode;
a second electrode;
a first wiring;
a second wiring;
a first measurement terminal; and
a second measurement terminal,
the cellular potential measurement container being configured so that a hole is formed on a surface of the container main body plate, the partition substrate is arranged on the surface of the container main body plate so as to cover the hole, the partition substrate has a through hole, the resin portion is provided on the surface of the container main body plate so as to surround the through hole, a space surrounded by the resin portion serves as a first solution reservoir for storing a first solution, an interior of the hole serves as a second solution reservoir for storing a second solution, a first end of the through hole is open toward the first solution reservoir while a second end of the through hole is open toward the second solution reservoir, the opening at the first end of the through hole can hold a cell, the first electrode is arranged on a surface of the partition substrate so that the first solution can come into contact with the first electrode, the second electrode is arranged on a rear surface of the partition substrate so that the second solution can come into contact with the second electrode,
the first solution reservoir, the second solution reservoir, the partition substrate, the first electrode, and the second electrode constitute a measurement unit, and
the first wiring, the second wiring, the first measurement terminal, and the second measurement terminal are arranged on the surface of the container main body plate,
wherein the cellular potential measurement container further comprises an electric signal amplifying device and a power supply terminal, the power supply terminal is connected electrically to the electric signal amplifying device, and one of the first electrode and the second electrode is connected electrically to the first measurement terminal via the electric signal amplifying device while the other one of the first electrode and the second electrode is connected electrically to the second measurement terminal.

17. The cellular potential measurement container according to claim 16, comprising a plurality of said measurement units, and the resin portion is provided for each of the measurement units.

18. The cellular potential measurement container according to claim 16, comprising a plurality of said measurement units,
wherein the resin portion is a resin plate having a plurality of holes, and the resin plate is arranged on the surface of the container main body plate in such a manner that the plurality of holes form the first solution reservoirs of the plurality of the measurement unit.

19. The cellular potential measurement container according to claim 16, wherein the first measurement terminal and the second measurement terminal are arranged at end portions on the surface of the container main body plate.

20. The cellular potential measurement container according to claim 16, wherein a second solution channel is formed inside the container main body plate, the hole forming the second solution reservoir communicates with the second solution channel, a first end of the second solution channel is open at the surface of the container main body plate so as to serve as an inlet for the second solution while a second end of the second solution channel is open at the surface of the container main body plate so as to serve as an outlet for the second solution.

21. The cellular potential measurement container according to claim 20, wherein flow direction control means for causing the second solution to flow toward the second solution reservoir is arranged at a position corresponding to the second solution reservoir in the second solution channel.

22. The cellular potential measurement container according to claim 21, wherein the flow direction control means is a protruding portion formed inside the second solution channel.

23. The cellular potential measurement container according to claim 20, comprising a plurality of said second solution channels, wherein one or a plurality of said measurement units are formed above each of the second solution channels.

24. The cellular potential measurement container according to claim 16, wherein the first wiring comprises a wiring pattern formed on the surface of the container main body plate and a conductive wire, and the wiring pattern and the first electrode connected electrically to each other through the conductive wire.

25. The cellular potential measurement container according to claim 16, wherein the second wiring is a wiring pattern formed on the surface of the container main body plate, and the second electrode on the rear surface of the partition substrate is arranged on an end portion of the wiring pattern.

26. The cellular potential measurement container according to claim 16, wherein the first wiring and the second wiring are encapsulated with the resin portion either partially or entirely.

27. The cellular potential measurement container according to claim 26, wherein at least the conductive wire is encapsulated with the resin portion.

28. The cellular potential measurement container according to claim 16, wherein an edge portion of the partition substrate is covered with the resin portion.

29. The cellular potential measurement container according to claim 16, comprising a plurality of said measurement units, a plurality of said electric signal amplifying devices, a plurality of said first measurement terminals, and the one second measurement terminal,
wherein one of a set of the first electrodes and a set of the second electrodes is connected to the first measurement terminals via the electric signal amplifying devices on a one-to-one basis, and the other one of the set of the first electrodes and the set of the second electrodes is connected to the second measurement terminal through a common wiring structure.

30. The cellular potential measurement container according to claim 16, wherein the partition substrate has a plurality of said through holes.
